(19) United States
(12) Patent Application Publication
(10) Pub. No.: US 2024/0431154 A1
(43) Pub. Date: Dec. 26, 2024

(54) DISPLAY DEVICE

(71) Applicant: Samsung Display Co., LTD., Yongin-si (KR)

(72) Inventors: YOOLGUK KIM, Yongin-si (KR); JIYOON KIM, Yongin-si (KR); HYEONSIK KIM, Yongin-si (KR); SANGHO LEE, Yongin-si (KR); HEEWOON IM, Yongin-si (KR)

(21) Appl. No.: 18/750,797

(22) Filed: Jun. 21, 2024

(30) Foreign Application Priority Data
Jun. 21, 2023 (KR) 10-2023-0079515

(51) Int. Cl. H10K 59/124; H10K 50/115; H10K 59/122

(52) U.S. Cl. CPC H10K 59/124; H10K 59/122; H10K 50/115

(57) ABSTRACT

A display device includes a first electrode, a second electrode disposed on the first electrode and facing the first electrode, a light emitting layer disposed between the first electrode and the second electrode and including a quantum dot, a metal oxide layer disposed between the first electrode and the second electrode and including a metal oxide, an auxiliary film disposed at the same level as the first electrode and including an inorganic material, and a pixel defining layer which covers at least a portion of the auxiliary film and which defines a pixel opening exposing a portion of the first electrode.

This application claims priority to Korean Patent Application No. 10-2023-0079515, filed on Jun. 21, 2023, and all the benefits accruing therefrom under 35 U.S.C. § 119, the content of which in its entirety is herein incorporated by reference.

### BACKGROUND

### 1. Field

The invention relates to a display device, and more particularly to a display device including a light emitting element.

### 2. Description of the Related Art

As information technology develops, the importance of a display device as a connection medium between a user and information is being highlighted. For example, the use of display devices such as a liquid crystal display device (LCD), an organic light emitting display device (OLED), a plasma display device (PDP) and a quantum dot display device is increasing.

The quantum dot display device may include a quantum dot light emitting element. The quantum dot light emitting element has an advantage of high chromaticity, high luminous efficiency, and multi-coloring.

### SUMMARY

Embodiments provide a display device having improved luminous efficiency.

A display device according to an embodiment includes a first electrode, a second electrode disposed on the first electrode and facing the first electrode, a light emitting layer disposed between the first electrode and the second electrode and including a quantum dot, a metal oxide layer disposed between the first electrode and the second electrode and including a metal oxide, an auxiliary film disposed at the same level as the first electrode and including an inorganic material, and a pixel defining layer which covers at least a portion of the auxiliary film and defines a pixel opening exposing a portion of the first electrode.

In an embodiment, the auxiliary film may include hydrogen.

In an embodiment, the auxiliary film may have a hydrogen content sufficient to emit hydrogen gas of about 1.0E+20 molecules/cm3 or more as the auxiliary film is heated to a temperature range between about 50° C. to about 550° C.

In an embodiment, the inorganic material included in the auxiliary film may include at least one of silicon oxide, silicon nitride, and silicon oxynitride.

In an embodiment, the auxiliary film may be continuously connected between a plurality of pixel areas which are disposed adjacent to each other and which are defined by the pixel opening.

In an embodiment, the inorganic material included in the auxiliary film may include a silicon semiconductor material.

In an embodiment, the auxiliary film may be disconnected between a plurality of pixel areas which are disposed adjacent to each other and which are defined by the pixel opening.

In an embodiment, the auxiliary film may cover a portion of the first electrode and may expose another portion of the first electrode.

In an embodiment, the auxiliary film may be disposed to be spaced apart from the first electrode.

In an embodiment, the metal oxide included in the metal oxide layer may include zinc-containing oxide.

In an embodiment, the metal oxide layer may include Mg-doped ZnO (ZnMgO).

In an embodiment, the pixel defining layer may have liquid repellency.

In an embodiment, the display device may further include an electron transport area located between the first electrode and the second electrode, wherein the metal oxide layer may be included in the electron transport area, and wherein the electron transport area may be disposed in between at least one of the first electrode and the light emitting layer, and the second electrode and the light emitting layer.

In an embodiment, the electron transport area may include at least one layer of a buffer layer, a hole blocking layer, an electron control layer, an electron transport layer, and an electron injection layer, and the metal oxide layer may be at least one of the buffer layer, the hole blocking layer, the electron control layer, the electron transport layer, and the electron injection layer.

A display device according to an embodiment includes a first electrode, a second electrode disposed on the first electrode and facing the first electrode, a light emitting layer disposed between the first electrode and the second electrode and including a quantum dot, a metal oxide layer disposed between the first electrode and the second electrode and including a metal oxide, an auxiliary film disposed between the first electrode and the second electrode and including an inorganic material, and a pixel defining layer which covers at least a portion of the auxiliary film and which defines a pixel opening exposing a portion of the first electrode.

In an embodiment, the auxiliary film may include hydrogen.

In an embodiment, the auxiliary film may have a hydrogen content sufficient to emit hydrogen gas of about 1.0E+20 molecules/cm3 or more as the auxiliary film is heated to a temperature range of between about 50° C. to about 550° C.

In an embodiment, the inorganic material included in the auxiliary film may include at least one of silicon oxide, silicon nitride, silicon oxynitride, and silicon semiconductor.

In an embodiment, the metal oxide included in the metal oxide layer may include zinc-containing oxide.

In an embodiment, the metal oxide layer may include Mg-doped ZnO (ZnMgO).

In an embodiment, the display device may further include a hole transport area disposed between the first electrode and the second electrode, and the auxiliary film may be disposed in between at least one the first electrode and the light emitting layer, and the second electrode and the light emitting layer.

In an embodiment, the display device may further include an electron transport area disposed between the first electrode and the second electrode, wherein the metal oxide layer may be included in the electron transport area, and wherein the electron transport area may be disposed in between at least one of the first electrode and the light emitting layer, and the second electrode and the light emitting layer.

In an embodiment, the electron transport area may include at least one layer of a buffer layer, a hole blocking layer, an electron control layer, an electron transport layer, and an electron injection layer, and the metal oxide layer may be at least one of the buffer layer, the hole blocking layer, the electron control layer, the electron transport layer, and the electron injection layer.

A display device according to an embodiment includes a substrate, a pixel circuit layer disposed on the substrate and including at least one transistor and a planarization layer covering the transistor, and a light emitting element layer disposed on the pixel circuit layer, wherein the light emitting element layer includes a first electrode disposed on the planarization layer, a second electrode disposed on the first electrode and facing the first electrode, a light emitting layer disposed between the first electrode and the second electrode and including a quantum dot, a metal oxide layer disposed between the first electrode and the second electrode and including a metal oxide, an auxiliary film disposed in at least one of the same level as the first electrode and a level located between the first electrode and the second electrode and including an inorganic material, and a pixel defining layer which covers at least a portion of the auxiliary film and which defines a pixel opening exposing a portion of the first electrode.

In an embodiment, the auxiliary film may include hydrogen, and the metal oxide included in the metal oxide layer may include zinc-containing oxide.

In an embodiment, the inorganic material included in the auxiliary film may include at least one of silicon oxide, silicon nitride, silicon oxynitride, and silicon semiconductor.

The display device according to an embodiment may include an auxiliary film including hydrogen. Accordingly, hydrogen may flow into a light emitting element from the auxiliary film.

In an embodiment, as hydrogen flows into a metal oxide layer of the light emitting element from the auxiliary film, an oxygen vacancy of the metal oxide layer may be reduced. Accordingly, deterioration of the metal oxide layer due to oxygen vacancy may be reduced or prevented. Accordingly, deterioration of the light emitting element may be reduced or prevented and luminous efficiency of the display device may be improved.

In particular, according to an embodiment, the auxiliary film may be disposed at the same level as a first electrode (e.g., a pixel electrode). In addition, the auxiliary film may be disposed between the first electrode and a second electrode (e.g., a common electrode). Accordingly, a distance between the auxiliary film and the metal oxide layer may be reduced as compared to a case where the auxiliary film is disposed below the first electrode. Accordingly, an inflow path of hydrogen flowing from the auxiliary film into the metal oxide layer may be shortened. Accordingly, hydrogen may flow more smoothly from the auxiliary film into the metal oxide layer and deterioration of the light emitting element may be further reduced or prevented.

In an embodiment, as the auxiliary film is disposed in at least one of the same level as the first electrode and a level between the first electrode and the second electrode, hydrogen supplied from the auxiliary film to the metal oxide layer may not be blocked by the first electrode. Accordingly, hydrogen may flow more smoothly from the auxiliary film to the light emitting element and deterioration of the light emitting element may be further reduced or prevented.

It is to be understood that both the foregoing general description and the following detailed description are exemplary and explanatory and are intended to provide further explanation of the invention as claimed.

### BRIEF DESCRIPTION OF THE DRAWINGS

Illustrative, non-limiting embodiments will be more clearly understood from the following detailed description taken in conjunction with the accompanying drawings.

FIG. 1 is a plan view illustrating a display device, according to an embodiment.

FIG. 2 is a cross-sectional view of the display device of FIG. 1 taken along line I-I′ of FIG. 1, according to an embodiment.

FIG. 3 is a cross-sectional view of the display device of FIG. 1 schematically illustrating an intermediate layer of FIG. 2, according to an embodiment.

FIG. 4 is a cross-sectional view of the display device of FIG. 1 schematically illustrating an intermediate layer of FIG. 2, according to an embodiment.

FIG. 5 is a cross-sectional view of the display device of FIG. 1 taken along line I-I′ of FIG. 1, according to an embodiment.

FIG. 6 is a cross-sectional view of the display device of FIG. 1 taken along line I-I′ of FIG. 1, according to an embodiment.

FIG. 7 is a cross-sectional view of the display device of FIG. 1 taken along line I-I′ of FIG. 1, according to an embodiment.

FIG. 8 is a cross-sectional view of the display device of FIG. 1 taken along line I-I′ of FIG. 1, according to an embodiment.

FIG. 9 is a cross-sectional view of the display device of FIG. 1 taken along line I-I′ of FIG. 1, according to an embodiment.

FIG. 10 is a cross-sectional view of the display device of FIG. 1 taken along line I-I′ of FIG. 1, according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element (or a region, a layer, a portion, or the like) is referred to as being related to another element, such as being “on”, “connected to” or “coupled to” another element, it may be directly disposed on, connected or coupled to the other element, or intervening elements may be disposed therebetween.

Like reference numerals or symbols refer to like elements throughout. In the drawings, the thickness, the ratio, and the size of the element are exaggerated for effective description of the technical contents. As used herein, the term “and/or” includes any and all combinations of one or more of the associated listed items.

The term “and/or,” includes all combinations of one or more of which associated configurations may define.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the scope of the inventive concept. Similarly, a second element, component, region, layer or section may be termed a first element, component, region, layer or section. As used herein, the singular forms, “a”, “an” and “the” are intended to include the plural forms as well, unless the context clearly indicates otherwise.

Also, terms such as “below”, “on lower side”, “above”, “on upper side”, or the like may be used to describe the relationships of the elements illustrated in the drawings. These terms have relative concepts and are described on the basis of the directions indicated in the drawings.

It will be further understood that the terms “comprise”, “includes” and/or “have”, when used in this specification, specify the presence of stated features, integers, steps, operations, elements, components, and/or groups thereof, but do not preclude the presence or addition of one or more other features, integers, steps, operations, elements, components, and/or groups thereof. As used herein, being “disposed directly on” may mean that there is no additional layer, film, region, plate, or the like between a part and another part such as a layer, a film, a region, a plate, or the like. For example, being “disposed directly on” may mean that two layers or two members are disposed without using an additional member such as an adhesive member, therebetween.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

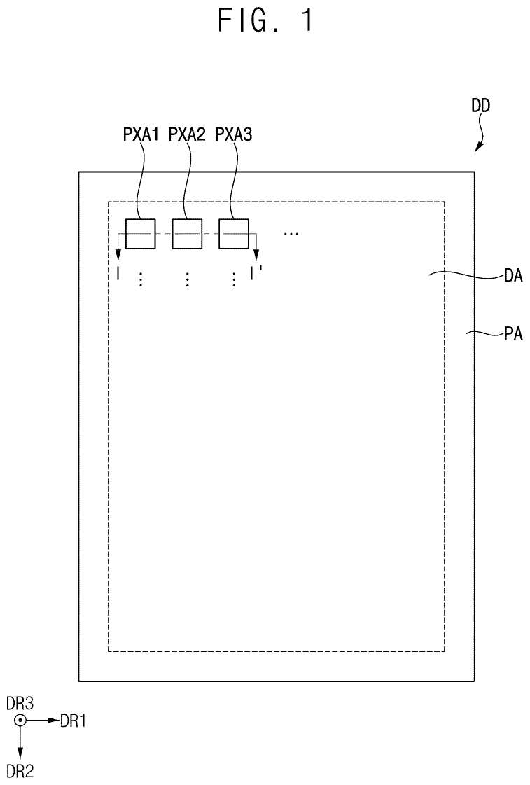

FIG. 1 is a plan view illustrating a display device, according to an embodiment.

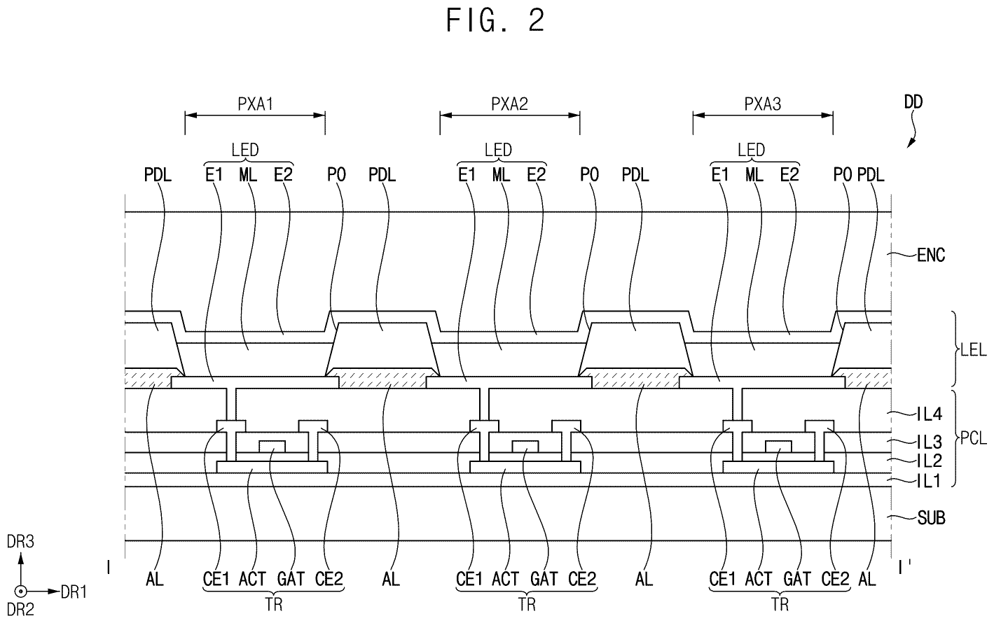

Referring to FIG. 1, a display device DD (e.g., a substrate SUB of FIG. 2) according to an embodiment may include a display area DA and a peripheral area PA. The display area DA may be an area that can display an image by generating light or adjusting a transmittance of light provided from an external light source. The peripheral area PA may be an area that does not display images. The peripheral area PA may be located around the display area DA. For example, the peripheral area PA may entirely surround the display area DA.

In an embodiment, the display area DA may include a plurality of pixel areas. The pixel areas may be arranged in a matrix form on a plane defined by a first direction DR1 and a second direction DR2 intersecting the first direction DR1. For example, the pixel areas may include a first pixel area PXA1, a second pixel area PXA2, and a third pixel area PXA3.

In an embodiment, the third direction DR3 may be a normal direction of the plane defined by the first direction DR1 and the second direction DR2. That is, the third direction DR3 may be perpendicular to both the first direction DR1 and the second direction DR2.

In an embodiment, each of the first pixel area PXA1, the second pixel area PXA2, and the third pixel area PXA3 may mean an area where light emitted from a light emitting element is emitted to the outside of the display device DD. For example, the first pixel area PXA1 may emit a first light, the second pixel area PXA2 may emit a second light, and the third pixel area PXA3 may emit a third light. In an embodiment, the first light may be red light, the second light may be green light, and the third light may be blue light. However, the invention is not limited thereto. For example, the first pixel area PXA1, the second pixel area PXA2 and the third pixel area PXA3 may be combined to emit yellow light, cyan light, and magenta light.

In an embodiment, each of the first pixel area PXA1, the second pixel area PXA2, and the third pixel area PXA3 may have a triangular planar shape, a square planar shape, a circular planar shape, an oval planar shape, or the like. In an embodiment, each of the first pixel area PXA1, the second pixel area PXA2, and the third pixel area PXA3 may have a rectangular planar shape. However, it is not necessarily limited thereto, and each of the first pixel area PXA1, the second pixel area PXA2, and the third pixel area PXA3 may have a planar shape other than a rectangle.

FIG. 2 is a cross-sectional view taken along line I-I′ of FIG. 1, according to an embodiment.

In an embodiment and referring to FIGS. 1 and 2, the display device DD may include a substrate SUB, a pixel circuit layer PCL, a light emitting element layer LEL, and an encapsulation layer ENC.

In an embodiment, the substrate SUB may include a transparent or opaque material. In an embodiment, some examples of materials that can be used as a substrate SUB may include glass, quartz, plastic, or the like. These can be used alone or in combination with each other.

In an embodiment, the pixel circuit layer PCL may be disposed on the substrate SUB. The pixel circuit layer PCL may include an inorganic layer, an organic layer, and a metal pattern. A pixel circuit may be implemented through the inorganic layer, the organic layer, and the metal pattern. The pixel circuit may drive the light emitting element.

In an embodiment, the pixel circuit layer PCL may include a first insulating layer IL1, a second insulating layer IL2, a third insulating layer IL3, a fourth insulating layer IL4, and a transistor TR. The transistor TR may include an active pattern ACT, a gate electrode GAT, a first connection electrode CE1, and a second connection electrode CE2. In an embodiment, the transistor TR may be disposed in the pixel areas PXA1, PXA2, and PXA3.

In an embodiment, the first insulating layer IL1 may be disposed on the substrate SUB. The first insulating layer IL1 may prevent impurities such as oxygen and moisture from diffusing into an upper portion of the substrate SUB. The first insulating layer IL1 may include an inorganic insulating material such as a silicon compound or metal oxide.

In an embodiment, the active pattern ACT may be disposed on the first insulating layer IL1. In an embodiment, the active pattern ACT may include a silicon semiconductor material or an oxide semiconductor material.

In an embodiment, the second insulating layer IL2 may be disposed on the first insulating layer IL1. The second insulating layer IL2 may cover the active pattern ACT. In an embodiment, the second insulating layer IL2 may be arranged in a pattern on the active pattern ACT to expose a portion of the active pattern ACT. For example, the second insulating layer IL2 may be disposed in a pattern on the active pattern ACT so as to overlap the gate electrode GAT. The second insulating layer IL2 may include an inorganic insulating material.

In an embodiment, the gate electrode GAT may be disposed on the second insulating layer IL2. In an embodiment, the gate electrode GAT may include metal, alloy, conductive metal oxide, transparent conductive material, or the like.

In an embodiment, the third insulating layer IL3 may be disposed on the second insulating layer IL2. In an embodiment, the third insulating layer IL3 may cover the gate electrode GAT. The third insulating layer IL3 may include an inorganic insulating material.

In an embodiment, the first connection electrode CE1 and the second connection electrode CE2 may be disposed on the third insulating layer IL3. The first connection electrode CE1 and the second connection electrode CE2 may be electrically connected to the active pattern ACT through contact holes formed in the third insulating layer IL3. Each of the first connection electrode CE1 and the second connection electrode CE2 may include a metal, alloy, conductive metal oxide, transparent conductive material, or the like.

In an embodiment, the fourth insulating layer IL4 may be disposed on the third insulating layer IL3. The fourth insulating layer IL4 may cover the first connection electrode CE1 and the second connection electrode CE2. The fourth insulating layer IL4 may include an organic insulating material. The fourth insulating layer IL4 may have a substantially flat upper surface in the display area DA. For example, the fourth insulating layer IL4 may be referred to as a planarization layer.

In an embodiment, the light emitting element layer LEL may be disposed on the pixel circuit layer PCL. The light emitting element layer LEL may include a light emitting element LED, an auxiliary film AL, and a pixel defining layer PDL. The light emitting element LED may include a first electrode E1, an intermediate layer ML, and a second electrode E2. In an embodiment, the light emitting element LED may be disposed in the pixel areas PXA1, PXA2, and PXA3. The light emitting element LED may be driven by the transistor TR of the pixel circuit layer PCL.

In an embodiment, the first electrode E1 may be disposed on the fourth insulating layer IL4. The first electrode E1 may be electrically connected to the transistor TR through a contact hole formed in the fourth insulating layer IL4. The first electrode E1 may include metal, alloy, conductive metal oxide, transparent conductive material, or the like.

In an embodiment, the auxiliary film AL may be disposed on the fourth insulating layer IL4. That is, the auxiliary film AL may be disposed at the same level as the first electrode E1. The auxiliary film AL may cover a portion of the first electrode E1 and expose another portion of the first electrode E1. For example, the auxiliary film AL may cover edges of the first electrode E1 and expose a central portion of the first electrode E1. However, the invention is not necessarily limited thereto.

In an embodiment, the auxiliary film AL may include an inorganic material. Examples of the inorganic material that can be used as the auxiliary film AL may include silicon oxide, silicon nitride, silicon oxynitride, silicon semiconductor, or the like. These can be used alone or in combination with each other. Examples of the silicon semiconductor may include amorphous silicon, polycrystalline silicon, or the like. Specifically, the silicon semiconductor may include amorphous silicon.

For example, in an embodiment, the auxiliary film AL may be a silicon nitride layer including silicon nitride. For another example, the auxiliary film AL may be an amorphous silicon layer including amorphous silicon. However, the invention is not necessarily limited thereto.

In an embodiment, the auxiliary film AL may include hydrogen (H). For example, in a process of forming the auxiliary film AL with an inorganic material, the auxiliary film AL including hydrogen (H) may be formed by reacting with a gas containing hydrogen. Specifically, in the process of forming the auxiliary film AL with silicon oxide, silicon nitride, and/or silicon oxynitride, an auxiliary film AL including hydrogen H may be formed by reacting with gases such as SiH2, SiH4, and Si2H6. For another example, after forming the auxiliary film AL with an inorganic material, the auxiliary film AL including hydrogen (H) may be formed by doping the auxiliary film AL with hydrogen (H). Specifically, after forming the auxiliary film AL with a silicon semiconductor, the auxiliary film AL including hydrogen (H) may be formed by doping the auxiliary film AL with hydrogen (H).

In an embodiment, the auxiliary film AL may have a hydrogen content sufficient to emit hydrogen gas of about 1.0E+20 molecules/cm³ or more as the auxiliary film is heated to a temperature of between about 50° C. to about 550° C. Specifically, the auxiliary film AL may have a hydrogen content sufficient to emit hydrogen gas of about 7.0E+21 molecules/cm3 or more as the auxiliary film is heated to a temperature of between about 50° C. to about 550° C. More preferably, the auxiliary film AL may have a hydrogen content sufficient to emit hydrogen gas of about 3.0E+21 molecules/cm3 or more as the auxiliary film is heated to a temperature of between about 50° C. to about 550° C. However, the invention is not necessarily limited thereto.

In an embodiment, as the auxiliary film AL includes hydrogen (H), hydrogen (H) may flow from the auxiliary film AL to the light emitting element LED. In an embodiment, the light emitting element LED may include a metal oxide layer including metal oxide. Specifically, the intermediate layer ML of the light emitting element LED may include the metal oxide layer. Oxygen vacancy may be generated inside the metal oxide layer. If an excessive amount of oxygen vacancy is generated inside the metal oxide layer, electrical properties of the metal oxide layer may change and charge transfer characteristics (e.g., current characteristics) of the metal oxide layer may deteriorate. Accordingly, the characteristics of the light emitting element LED may deteriorate.

However, according to an embodiment, as the light emitting element layer LEL includes the auxiliary film AL including hydrogen (H), hydrogen (H) may flow from the auxiliary film AL to the light emitting element LED. That is, hydrogen (H) may flow into the metal oxide layer from the auxiliary film AL. As hydrogen (H) flows into the metal oxide layer from the auxiliary film AL, the oxygen vacancy of the metal oxide layer may be reduced. Accordingly, deterioration of the metal oxide layer due to oxygen vacancy may be reduced or prevented. Accordingly, deterioration of the light emitting element LED may be reduced or prevented and luminous efficiency of the display device DD may be improved.

In particular, according to an embodiment, as the auxiliary film AL is disposed at the same level as the first electrode E1, a distance between the auxiliary film AL and the metal oxide layer may be reduced as compared to a case where the auxiliary film AL is disposed below the first electrode E1. Accordingly, an inflow path of hydrogen (H) flowing from the auxiliary film AL into the metal oxide layer may be shortened. Accordingly, hydrogen (H) may flow more smoothly from the auxiliary film AL into the metal oxide layer and deterioration of the light emitting element LED may be further reduced or prevented.

In addition, according to an embodiment, as the auxiliary film AL is disposed at the same level as the first electrode E1, hydrogen (H) supplied from the auxiliary film AL to the metal oxide layer may not blocked by the first electrode E1. Accordingly, hydrogen (H) may flow more smoothly from the auxiliary film AL to the light emitting element LED and deterioration of the light emitting element LED may be further reduced or prevented.

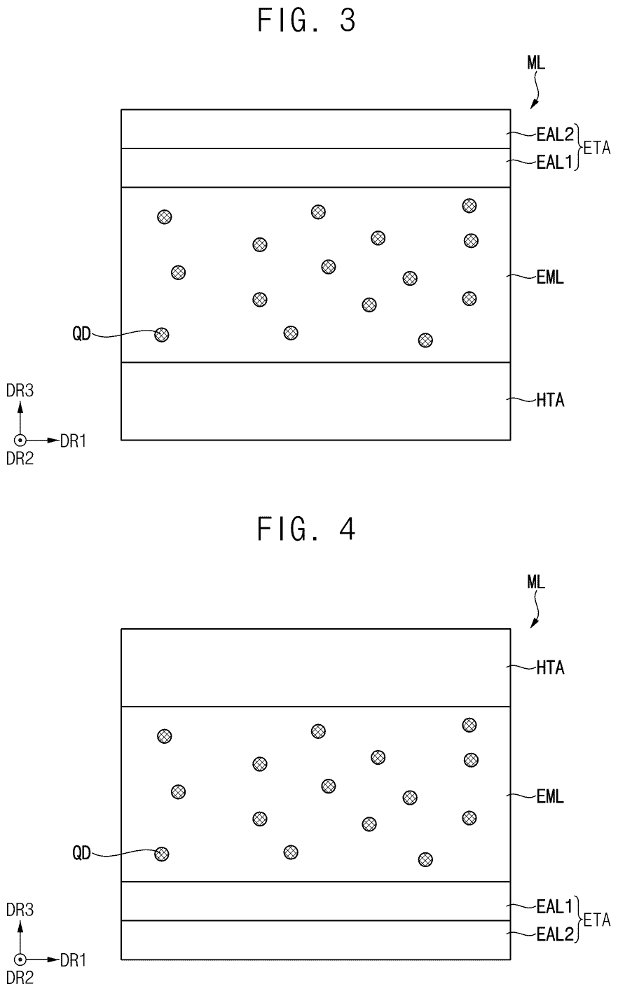

The intermediate layer ML including the metal oxide layer will be described in more detail later with further reference to FIGS. 3 and 4.

In an embodiment, the auxiliary film AL may be continuously connected between pixel areas which are disposed adjacent to each other. That is, as shown in FIG. 2, the auxiliary film AL may not be disconnected between the first pixel area PXA1 and the second pixel area PXA2, and the auxiliary film AL may not be disconnected between the second pixel area PXA2 and the third pixel area PXA3. For example, the auxiliary film AL may have a grid shape in a plan view. However, the invention is not necessarily limited thereto.

In an embodiment, the pixel defining layer PDL may be disposed on the first electrode E1 and the auxiliary film AL. The pixel defining layer PDL may include an organic material. Examples of the organic material that can be used as the pixel defining layer PDL may include photoresist, polyacrylic resin, polyimide resin, acrylic resin, or the like. These may be used alone or in combination with each other.

In an embodiment, the pixel defining layer PDL may expose a portion of the first electrode E1. Specifically, the pixel defining layer PDL may define a pixel opening PO which exposes a portion of the first electrode E1. For example, the pixel defining layer PDL may have a grid shape in a plan view. The pixel areas PXA1, PXA2, and PXA3 may be defined by the pixel opening PO of the pixel defining layer PDL.

In an embodiment, the pixel defining layer PDL may have liquid repellency. Specifically, an upper surface of the pixel defining layer PDL may have liquid repellency. In this specification, liquid repellency may mean a property of repelling a predetermined solution and preventing the solution from permeating well. For example, a surface bonding force of the solution with a liquid-repellent surface is relatively small, and a surface tension of the solution disposed on the liquid-repellent surface may increase.

In an embodiment, as the pixel defining layer PDL has liquid repellency, in a process of forming the intermediate layer ML in the pixel opening PO, a phenomenon of a material discharged into the pixel opening PO through an inkjet printing method, overflowing to the upper surface of the PDL may be reduced or prevented. Accordingly, defects in a manufacturing process of the display device DD may be reduced or prevented.

In an embodiment, the pixel defining layer PDL may entirely cover the auxiliary film AL. That is, the auxiliary film AL may not be exposed by the pixel defining layer PDL. For example, a point where a side surface of the pixel defining layer PDL contacts the upper surface of the first electrode E1 and a point where a side surface of the auxiliary film AL contacts the upper surface of the first electrode E1 may be same. However, the invention is not necessarily limited thereto.

In an embodiment, the intermediate layer ML may be disposed in the pixel opening PO of the pixel defining layer PDL. That is, the intermediate layer ML may be disposed on the first electrode E1. In an embodiment, the intermediate layer ML may include a material which emits light. For example, the intermediate layer ML corresponding to the first pixel area PXA1 may include a material which emits the first light, the intermediate layer ML corresponding to the second pixel area PXA2 may include a material which emits the second light, and the intermediate layer ML corresponding to the third pixel area PXA3 may include a material which emits the third light. In an embodiment, the first light may be red light, the second light may be green light, and the third light may be blue light. However, the invention is not limited thereto. A structure of the intermediate layer ML will be described in more detail later with further reference to FIGS. 3 and 4.

In an embodiment, the second electrode E2 may be disposed on the intermediate layer ML. The second electrode E2 may include a conductive material such as a metal, alloy, conductive metal nitride, conductive metal oxide, or transparent conductive material. In an embodiment, the second electrode E2 may extend continuously across a plurality of pixels.

As a result, in an embodiment, the light emitting element LED corresponding to the first pixel area PXA1 may emit the first light, and the light emitting element LED corresponding to the second pixel area PXA2 may emit the second light. The light emitting element LED corresponding to the third pixel area PXA3 may emit the third light. In an embodiment, the first light may be red light, the second light may be green light, and the third light may be blue light. However, the invention is not limited thereto.

In an embodiment, the encapsulation layer ENC may be disposed on the light emitting element layer LEL. The encapsulation layer ENC may protect the light emitting element LED from external moisture, heat, shock, or the like. Although not shown, the encapsulation layer ENC may include a first inorganic encapsulation layer, an organic encapsulation layer disposed on the first inorganic encapsulation layer, and a second inorganic encapsulation layer disposed on the organic encapsulation layer.

FIG. 3 is a cross-sectional view of the display device of FIG. 1 schematically illustrating an intermediate layer of FIG. 2, according to an embodiment.

Referring further to FIG. 3, in an embodiment, the intermediate layer ML may include a hole transport area HTA, a light emitting layer EML, and an electron transport area ETA sequentially stacked on the first electrode E1. In this embodiment, the light emitting element LED may be a conventional type light emitting element in which the first electrode E1 is an anode and the second electrode E2 is a cathode.

FIG. 4 is a cross-sectional view of the display device of FIG. 1 schematically illustrating an intermediate layer of FIG. 2, according to an embodiment.

In an embodiment and referring further to FIG. 4, the intermediate layer ML may include an electron transport area ETA, a light emitting layer EML, and a hole transport area HTA sequentially stacked on the first electrode E1. In this embodiment, the light emitting element LED may be an inverted type of light emitting element in which the first electrode E1 is a cathode and the second electrode E2 is an anode.

Hereinafter, with further reference to FIGS. 3 and 4, a structure of the intermediate layer ML included in the light emitting element LED will be described in more detail.

As described above, in an embodiment, the intermediate layer ML may include the hole transport area HTA, the light emitting layer EML, and the electron transport area ETA.

In an embodiment, the hole transport area HTA may have i) a single layer structure formed of a single layer of a single material, ii) a single layer structure formed of a single layer of a plurality of different materials, or iii) a multi-layer structure having a plurality of layers of a plurality of different materials.

In an embodiment, the hole transport area HTA may include at least one layer of a hole injection layer, a hole transport layer, a light emission auxiliary layer, and an electron blocking layer.

For example, in an embodiment, the hole transport area HTA may have a single layer structure formed of a single layer of a plurality of different materials, or a multi-layer structure of hole injection layer/hole transport layer, a hole injection layer/hole transport layer/light emission auxiliary layer, a hole injection layer/light emission auxiliary layer, a hole transport layer/light emission auxiliary layer, or a hole injection layer/hole transport layer/electron blocking layer sequentially stacked on the first electrode E1. However, the invention is not necessarily limited thereto.

In an embodiment, the hole transport area HTA may include an amorphous inorganic or organic material. A thickness of the hole transport area HTA may be in the range of between about 100 Å to about 10000 Å, for example, more specifically in the range of between about 100 Å to about 1000 Å. If the hole transport area HTA includes at least one of the hole injection layer and the hole transport layer, a thickness of the hole injection layer may be in the range of about 100 Å to about 9000 Å, and more specifically, in the range of about 100 Å to about 1000 Å, and a thickness of the hole transport layer may be in the range of about 50 Å to about 2000 Å, and more specifically, in the range of about 100 Å to about 1500 Å. When the thicknesses of the hole transport area HTA, the thickness of the hole injection layer, and the thickness of the hole transport layer satisfy the ranges described above, satisfactory hole transport characteristics may be obtained without a substantial increase in driving voltage.

In an embodiment, the light emission auxiliary layer may increase light emission efficiency by compensating for an optical resonance distance according to the wavelength of the light emitted from the light emitting layer EML, and the electron blocking layer may prevent electron injection from the electron transport area ETA.

In an embodiment, the light emitting layer EML may include a material which emits light. For example, the light emitting layer EML corresponding to the first pixel area PXA1 may include a material which emits the first light, and the light emitting layer EML corresponding to the second pixel area PXA2 may include a material which emits the second light, and the light emitting layer EML corresponding to the third pixel area PXA3 may include a material which emits the third light. In an embodiment, the first light may be red light, the second light may be green light, and the third light may be blue light. However, the invention is not limited thereto.

For example, in an embodiment, the light emitting layer EML may include a quantum dot QD, where the quantum dot QD may emit light when stimulated by light. For example, the quantum dot QD may include a group II-VI semiconductor compound, a group III-VI semiconductor compound, a group III-V semiconductor compound, a group IV-VI semiconductor compound, a group IV element or compound, a group I-III-VI semiconductor compound, or the like. These can be used alone or in combination with each other.

In an embodiment, examples of the II-VI group semiconductor compound may include binary compounds such as CdS, CdSe, CdTe, ZnS, ZnSe, ZnTe, ZnO, HgS, HgSe, HgTe, MgS, MgSe, etc., ternary compounds such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe MgZnS, MgZnSe, etc., quaternary compounds such as CdZnSeS, CdZnSeTe, CdZnSTe, CdHgSeS, CdHgSeTe, CdHgSTe, HgZnSeS, HgZnSeTe, HgZnSTe, etc., or any combination thereof.

In an embodiment, examples of the III-VI group semiconductor compound may include binary compounds such as In₂S₃, Ga₂S₃, etc., ternary compounds such as InGaS3, InGaSe₃, etc., or any combination thereof.

In an embodiment, examples of the group III-V semiconductor compound may include binary compounds such as GaN, GaP, GaAs, GaSb, AlN, AlP, AlAs, AlSb, InN, InP, InAs, InSb, etc., ternary compounds such as GaNP, GaNAs, GaNSb, GaPAs, GaPSb, AlNP, AlNAs, AlNSb, AlPAs, AlPSb, InAsP, InGaP, InGaAs, InAlP, InNP, InNAs, InNSb, InPAs, InPSb, GaAlNP, etc., quaternary compounds such as GaAlNAs, GaAlNSb, GaAlPAs, GaAlPSb, GaInNP, GaInNAs, GaInNSb, GalnPAs, GaInPSb, InAlNP, InAlNAs, InAlNSb, InAlPAs, InAlPSb, etc., or any combination thereof. The group III-V semiconductor compound may further include a group II metal (e.g., InZnP)

In an embodiment, examples of the IV-VI group semiconductor compound may include binary compounds such as SnS, SnSe, SnTe, PbS, PbSe, PbTe, etc., ternary compounds such as SnSeS, SnSeTe, SnSTe, PbSeS, PbSeTe, PbSTe, SnPbS, SnPbSe, SnPbTe, etc., quaternary compounds such as SnPbSSe, SnPbSeTe, SnPbSTe, etc., or any combination thereof.

In an embodiment, examples of the group IV element or compound may include Si and/or Ge; binary compounds such as SiC, SiGe, etc., or any combination thereof.

In an embodiment, examples of the Group I-III-VI semiconductor compound may include ternary compounds such as AgInS, AgInS₂, CuInS, CuInS₂, CuGaO₂, AgGaO₂, AgAlO₂, etc., or any combination thereof. The Group I-III-VI semiconductor compound may further include a Group II element. For example, the group I-III-VI semiconductor compound may include a quaternary element compound such as CuInZnS.

In an embodiment, the quantum dot QD may have a single structure with homogeneous components and composition, or a complex structure such as a core-shell structure, a gradient structure, or the like.

In an embodiment, the quantum dots QD may have a core-shell structure including a core including a first semiconductor crystal and a shell including a second semiconductor crystal. The core and the shell may include different materials from each other.

In an embodiment, the shell may serve as a protective layer to maintain semiconductor properties by preventing chemical denaturation of the core and/or as a charging layer to impart electrophoretic properties to the quantum dot QD. The shell may have a single-layer structure or a multi-layer structure. An interface between the core and the shell may have a concentration gradient in which the concentration of elements in the shell decreases toward the center. Examples of the shell of the quantum dot QD may include oxides of metals or non-metals, semiconductor compounds, or combinations thereof.

For example, in an embodiment, in the core-shell structure, each material forming the core and the shell may be selected from the semiconductor compounds described above.

In an embodiment, the light emitting layer EML may be formed by applying a composition for forming a light emitting layer in which the quantum dot QD is dispersed in a solvent on the first electrode E1 and volatilizing the solvent. The composition for forming the light emitting layer may be performed using a spin coat method, a casting method, a micro gravure coat method, a gravure coat method, a bar coat method, a roll coat method, a wire bar coat method, a dip coat method, a spray coat method, a screen-printing method, a flexographic method, an offset method, an ink jet printing method, or the like.

In an embodiment, the solvent may be water, hexane, chloroform, toluene, or the like, but is not necessarily limited as long as it can dissolve the material used to form the light emitting layer.

In an embodiment, the electron transport area ETA may have i) a single layer structure formed of a single layer of a single material, ii) a single layer structure formed of a single layer of a plurality of different materials, or iii) a multi-layer structure having a plurality of layers of a plurality of different materials. Preferably, the electron transport area ETA may have a multi-layer structure having a plurality of layers of a plurality of different materials, as shown in FIGS. 3 and 4. For example, the electron transport area ETA may include a first electron auxiliary layer EAL1 and a second electron auxiliary layer EAL2.

In an embodiment, the first electron auxiliary layer EAL1 may include the metal oxide layer. The metal oxide layer may include a conductive metal oxide, a fullerene derivative, or a combination thereof. For example, the metal oxide layer may include Mg-doped ZnO (ZnMgO), Al-doped ZnO (AZO), Ga-doped ZnO (GZO), In-doped ZnO (IZO), Al-doped SnO2, Ga-doped SnO2, In doped SnO2, Al doped TiO2, Ga-doped TiO2, In-doped TiO2, In2O3, Nb2O5, Fe2O3, CeO2, SrTiO3, Zn2SnO4, BaSnO3, In2S3, ZnSiO, PC60BM, PC70BM, Mg doped In2O3, Al doped In2O3, Ga doped In2O3, Mg doped Nb2O5, Al doped Nb2O5, Ga doped Nb2O5, Mg doped Fe2O3, Al doped Fe2O3, Ga doped Fe2O3, In doped Fe2O3, Mg doped CeO2, Al doped CeO2, Ga doped CeO2, In doped CeO2, Mg doped SrTiO3, Al doped SrTiO3, Ga doped SrTiO3, In doped SrTiO3, Mg doped Zn2SnO4, Al doped Zn2SnO4, Ga doped Zn2SnO4, In doped Zn2SnO4, Mg doped BaSnO3, Al doped BaSnO3, Ga doped BaSnO3, In doped BaSnO3, Mg doped In2S3, Al doped In2S3, Ga doped In2S3, In doped In2S3, Mg doped ZnSiO, and may include Al-doped ZnSiO, Ga-doped ZnSiO, In-doped ZnSiO, or a combination thereof. Specifically, the metal oxide layer may include zinc-containing oxide. For example, the metal oxide layer may include Mg-doped ZnO (ZnMgO).

In an embodiment, the second electron auxiliary layer EAL2 may include an amorphous inorganic material or an organic material. The inorganic material included in the second electron auxiliary layer EAL2 may be an n-type inorganic semiconductor. For example, The inorganic material included in the second electron auxiliary layer EAL2 may be an n-type inorganic semiconductor such as a compound containing Zn doped with a metal such as B, Al, Ga, In, Ti, V, Nb, Ta, Db, Cr, Mo, W, or Sg, and a non-metallic element such as F, Cl, Br, or I; or a spontaneous n-type inorganic semiconductor such as ZnO.

In an embodiment, the electron transport area ETA may include at least one layer of a buffer layer, a hole blocking layer, an electron control layer, an electron transport layer, and an electron injection layer, but the invention is not necessarily limited thereto. That is, the metal oxide layer may be at least one of the buffer layer, the hole blocking layer, the electron control layer, the electron transport layer, and the electron injection layer.

In an embodiment, the first electron auxiliary layer EAL1 may be the electron transport layer, and the second electron auxiliary layer EAL2 may be the electron injection layer. That is, the metal oxide layer may be the electron transport layer. However, the invention is not necessarily limited thereto.

In an embodiment, a thickness of the buffer layer, a thickness of the hole blocking layer, or a thickness of the electron control layer may independently be within a range of between about 20 Å to about 1000 Å, specifically in a range between about 30 Å to about 300 Å. When the thickness of the buffer layer, the thickness of the hole blocking layer, or the thickness of the electron control layer satisfies the ranges described above, excellent hole blocking characteristics or electron control characteristics may be obtained without a substantial increase in driving voltage.

In an embodiment, the electron transport area ETA (e.g., the electron transport layer in the electron transport area ETA) may further include a metal-containing material in addition to the materials described above.

In an embodiment, the metal-containing material may include at least one of an alkaline metal complex and an alkaline earth metal complex. Moreover, metal ions of the alkaline metal complex may be selected from Li ions, Na ions, K ions, Rb ions, and Cs ions, and metal ions of the alkaline earth metal complex may be selected from Be ions, Mg ions, Ca ions, Sr ions, and Ba ions. Ligands coordinated to the metal ions of the alkaline metal complex and the alkaline earth metal complex are, independently of each other, hydroxyquinoline, hydroxyisoquinoline, hydroxybenzoquinoline, hydroxyacridine, hydroxyphenanthridine, hydroxyphenyloxazole, hydroxyphenylthiazole, hydroxydiphenyloxadiazole, hydroxydiphenylthiadiazole, hydroxyphenylpyridine, hydroxyphenylbenzoimidazole, hydroxyphenylbenzothiazole, bipyridine, phenanthroline, cyclopentadiene, or the like, but is not necessarily limited thereto.

As described above, according to an embodiment, the electron transport area ETA (e.g., the first electron auxiliary layer EAL1) of the light emitting element LED may include the metal oxide layer, and oxygen vacancy may be generated inside the metal oxide layer. If an excessive amount of oxygen vacancy is generated inside the metal oxide layer, electrical properties of the metal oxide layer may change and charge transfer characteristics (e.g., current characteristics) of the metal oxide layer may deteriorate. Accordingly, the characteristics of the light emitting element LED may deteriorate.

However, according to an embodiment, as the light emitting element layer LEL (see FIG. 2) includes the auxiliary film AL including hydrogen (H), hydrogen (H) may flow from the auxiliary film AL to the metal oxide layer of the light emitting element LED. As hydrogen (H) flows into the metal oxide layer from the auxiliary film AL, the oxygen vacancy of the metal oxide layer may be reduced. Accordingly, deterioration of the metal oxide layer due to oxygen vacancy may be reduced or prevented. Accordingly, deterioration of the light emitting element LED may be reduced or prevented and luminous efficiency of the display device DD may be improved.

In particular, according to an embodiment, as the auxiliary film AL is disposed at the same level as the first electrode E1, a distance between the auxiliary film AL and the metal oxide layer may be reduced as compared to a case where the auxiliary film AL is disposed below the first electrode E1. Accordingly, an inflow path of hydrogen (H) flowing from the auxiliary film AL into the metal oxide layer may be shortened. Accordingly, hydrogen (H) may flow more smoothly from the auxiliary film AL into the metal oxide layer and deterioration of the light emitting element LED may be further reduced or prevented.

In addition, according to embodiment, as the auxiliary film AL is disposed at the same level as the first electrode E1, hydrogen (H) supplied from the auxiliary film AL to the metal oxide layer may not be blocked by the first electrode E1. Accordingly, hydrogen (H) may flow more smoothly from the auxiliary film AL to the light emitting element LED and deterioration of the light emitting element LED may be further reduced or prevented.

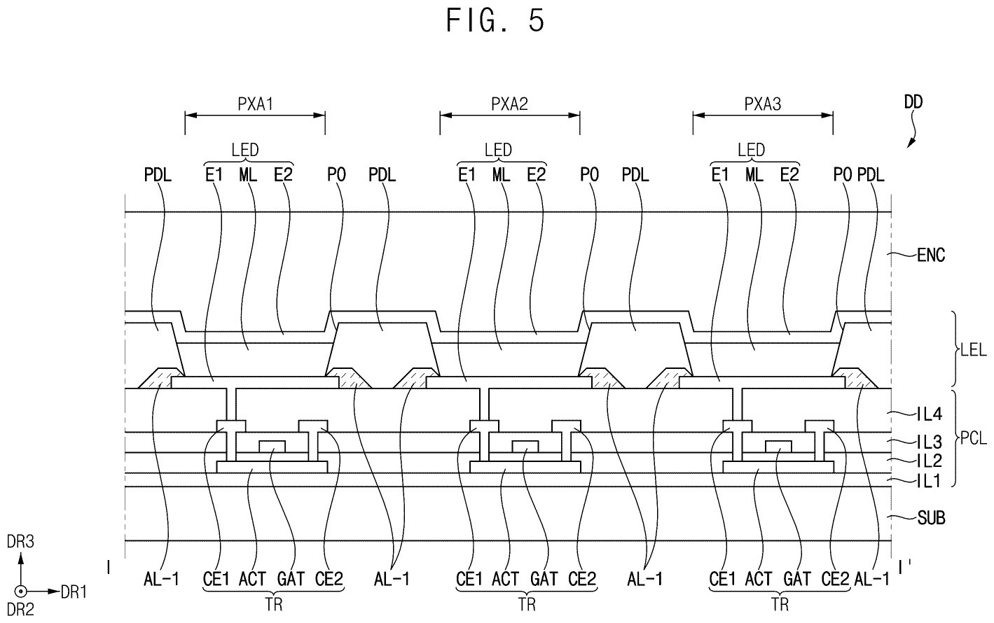

FIG. 5 is a cross-sectional view of a display device taken along line I-I′ of FIG. 1, according to an embodiment.

In an embodiment, the display device DD described with reference to FIG. 5 may be substantially the same as the display device DD described with reference to FIG. 2 except for including an auxiliary film AL-1 instead of the auxiliary film AL. Additionally, the auxiliary film AL-1 may be substantially the same as the auxiliary film AL except for being disconnected between the pixel areas which are adjacent. Therefore, redundant descriptions are omitted or simplified.

Referring to FIG. 5, in an embodiment, the display device DD may include the auxiliary film AL-1. The auxiliary film AL-1 may be disposed on the fourth insulating layer IL4. That is, the auxiliary film AL-1 may be disposed at the same level as the first electrode E1.

In an embodiment, the auxiliary film AL-1 may include hydrogen (H). Accordingly, hydrogen (H) may flow into the light emitting element LED from the auxiliary film AL-1. That is, hydrogen (H) may flow into the metal oxide layer from the auxiliary film AL-1.

In an embodiment, the auxiliary film AL-1 may be disconnected between the pixel areas which are located adjacent to each other. That is, as shown in FIG. 5, the auxiliary film AL-1 may be disconnected between the first pixel area PXA1 and the second pixel area PXA2, and the auxiliary film AL-1 may be disconnected between the second pixel area PXA2 and the third pixel area PXA3.

In an embodiment, as the auxiliary film AL-1 is disconnected between the pixel areas which are located adjacent to each other, leakage of current by the auxiliary film AL-1 between the pixel areas which are located adjacent to each other may be reduced or prevented. For example, as the auxiliary film AL-1 is disconnected between the pixel areas which are located adjacent to each other, leakage of current by the auxiliary film AL-1 between the pixel areas which are located adjacent to each other may be reduced or prevented even when the auxiliary film AL-1 includes a silicon semiconductor.

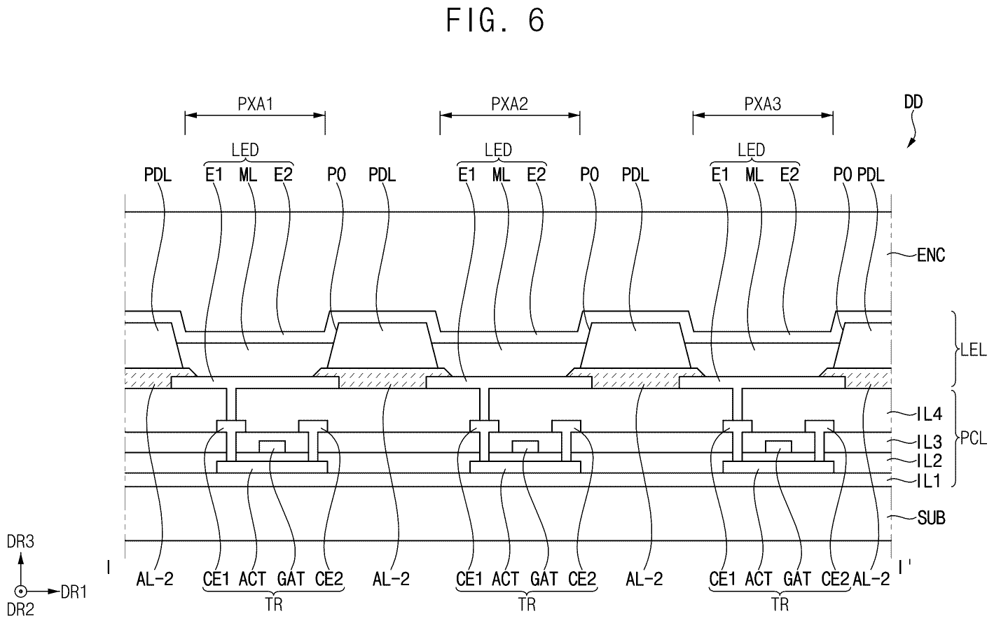

FIG. 6 is a cross-sectional view of a display device taken along line I-I′ of FIG. 1, according to an embodiment.

In an embodiment, the display device DD described with reference to FIG. 6 may be substantially the same as the display device DD described with reference to FIG. 2 except for including an auxiliary film AL-2 instead of the auxiliary film AL. Additionally, the auxiliary film AL-2 may be substantially the same as the auxiliary film AL except for being exposed from the pixel defining layer PDL. Therefore, redundant descriptions are omitted or simplified.

Referring to FIG. 6, in an embodiment, the display device DD may include the auxiliary film AL-2. The auxiliary film AL-2 may be disposed on the fourth insulating layer IL4. That is, the auxiliary film AL-2 may be disposed at the same level as the first electrode E1.

In an embodiment, the auxiliary film AL-2 may include hydrogen (H). Accordingly, hydrogen (H) may flow into the light emitting element LED from the auxiliary film AL-2. That is, hydrogen (H) may flow into the metal oxide layer from the auxiliary film AL-2.

In an embodiment, a portion of the auxiliary film AL-2 may be covered by the pixel defining layer PDL, and another portion of the auxiliary film AL-2 may be exposed from the pixel defining layer PDL. That is, the pixel defining layer PDL may partially cover the auxiliary film AL-2. For example, the pixel defining layer PDL may be disposed on the auxiliary film AL-2 and spaced apart from the first electrode E1. Accordingly, the auxiliary film AL-2 may directly contact the intermediate layer ML.

In an embodiment, as the auxiliary film AL-2 directly contacts the intermediate layer ML, an inflow path of hydrogen (H) flowing from the auxiliary film AL-2 to the light emitting element LED may be further shortened. Accordingly, hydrogen (H) may flow more smoothly from the auxiliary film AL-2 into the metal oxide layer of the light emitting element LED and deterioration of the light emitting element LED may be further reduced or prevented.

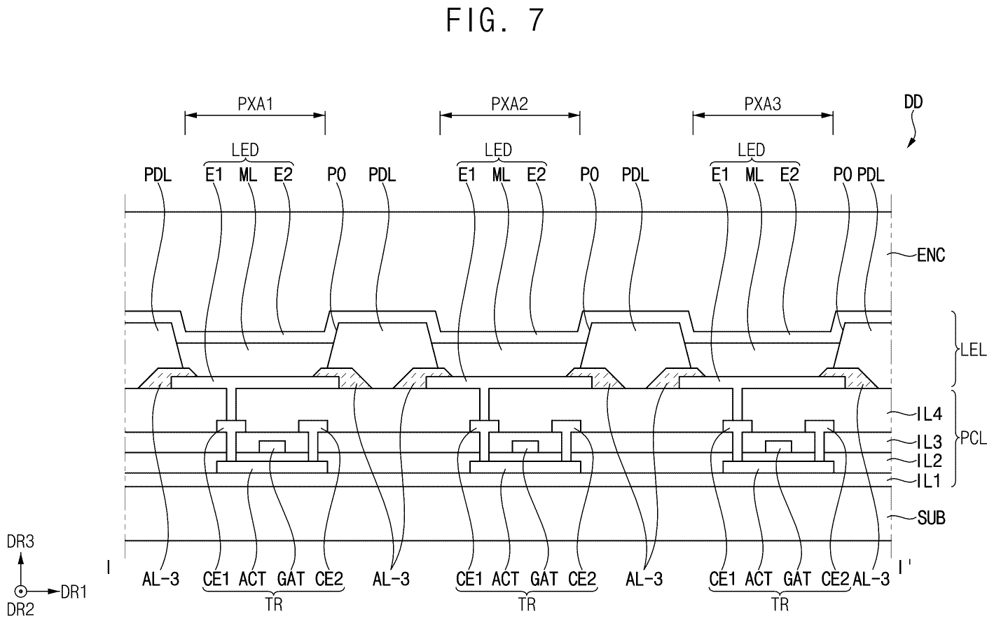

FIG. 7 is a cross-sectional view of a display device taken along line I-I′ of FIG. 1, according to an embodiment.

In an embodiment, the display device DD described with reference to FIG. 7 may be substantially the same as the display device DD described with reference to FIG. 2 except for including an auxiliary film AL-3 instead of the auxiliary film AL. Additionally, the auxiliary film AL-3 may be substantially the same as the auxiliary film AL except for being disconnected between the pixel areas which are located adjacent to each other and being exposed from the pixel defining layer PDL. Therefore, redundant descriptions are omitted or simplified.

Referring to FIG. 7, in an embodiment, the display device DD may include the auxiliary film AL-3, where the auxiliary film AL-3 may be disposed on the fourth insulating layer IL4. That is, the auxiliary film AL-3 may be disposed at the same level as the first electrode E1.

In an embodiment, the auxiliary film AL-3 may include hydrogen (H). Accordingly, hydrogen (H) may flow into the light emitting element LED from the auxiliary film AL-3. That is, hydrogen (H) may flow into the metal oxide layer from the auxiliary film AL-3.

In an embodiment, a portion of the auxiliary film AL-3 may be covered by the pixel defining layer PDL, and another portion of the auxiliary film AL-3 may be exposed from the pixel defining layer PDL. That is, the pixel defining layer PDL may partially cover the auxiliary film AL-3. For example, the pixel defining layer PDL may be disposed on the auxiliary film AL-3 and spaced apart from the first electrode E1. Accordingly, the auxiliary film AL-3 may directly contact the intermediate layer ML.

In an embodiment, even when a portion of the auxiliary film AL-3 is exposed from the pixel defining layer PDL, the auxiliary film AL-3 may be disconnected between the pixel areas which are located adjacent to each other. That is, as shown in FIG. 7, the auxiliary film AL-3 may be disconnected between the first pixel area PXA1 and the second pixel area PXA2, and the auxiliary film AL-3 may be disconnected between the second pixel area PXA2 and the third pixel area PXA3.

In an embodiment, as the auxiliary film AL-3 is disconnected between the pixel areas which are located adjacent to each other, leakage of current by the auxiliary film AL-3 between the pixel areas which are located adjacent to each other may be reduced or prevented.

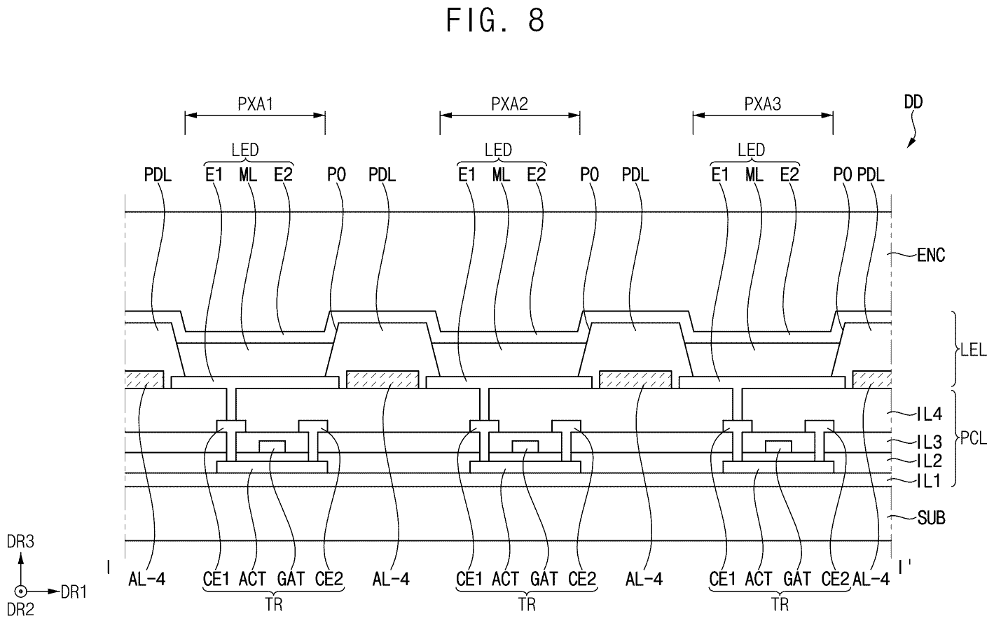

FIG. 8 is a cross-sectional view of a display device taken along line I-I′ of FIG. 1, according to an embodiment.

In an embodiment, the display device DD described with reference to FIG. 8 may be substantially same as the display device DD described with reference to FIG. 2 except for including an auxiliary film AL-4 instead of the auxiliary film AL. Additionally, the auxiliary film AL-4 may be substantially the same as the auxiliary film AL except for being spaced apart from the first electrode E1. Therefore, redundant descriptions are omitted or simplified.

Referring to FIG. 8, in an embodiment, the display device DD may include the auxiliary film AL-4 where the auxiliary film AL-4 may be disposed on the fourth insulating layer IL4. That is, the auxiliary film AL-4 may be disposed at the same level as the first electrode E1.

In an embodiment, the auxiliary film AL-4 may include hydrogen (H). Accordingly, hydrogen (H) may flow into the light emitting element LED from the auxiliary film AL-4. That is, hydrogen (H) may flow into the metal oxide layer from the auxiliary film AL-4.

In an embodiment, the auxiliary layer AL-4 may be spaced apart from the first electrode E1. That is, the auxiliary layer AL-4 may expose an entire portion of the first electrode E1. For example, the auxiliary layer AL-4 may be arranged in a pattern form that is separate from the first electrode E1 between the pixel areas which are located adjacent to each other. That is, as shown in FIG. 8, the auxiliary layer AL-4 may be disposed between the first pixel area PXA1 and the second pixel area PXA2 and between the second pixel area PXA2 and the third pixel area PXA3 in a pattern form. However, the invention is not necessarily limited thereto, and the auxiliary layer AL-4 may have a grid shape which does not cover the first electrode E1 in a plan view.

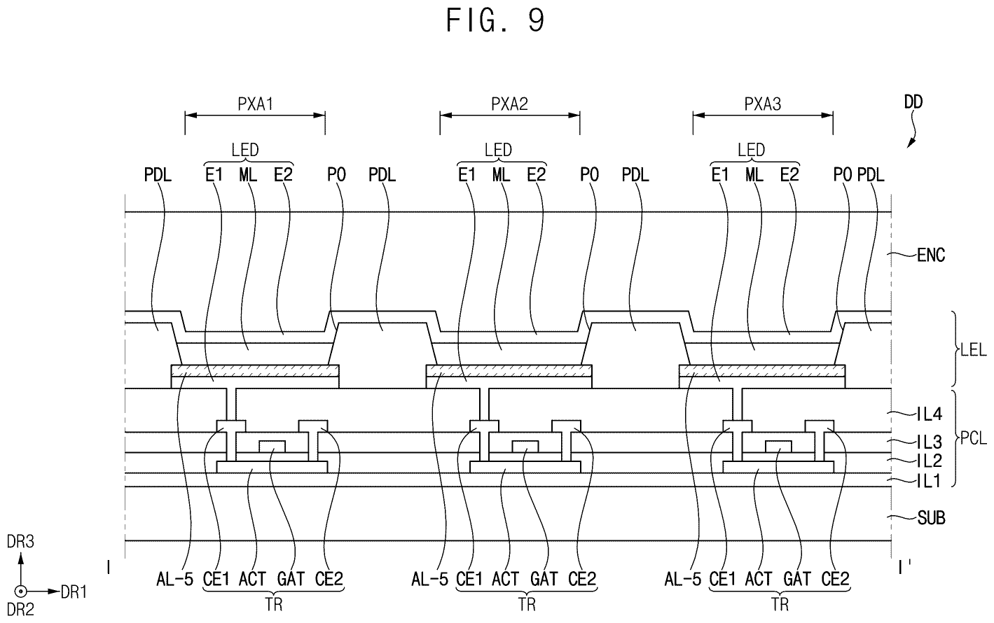

FIG. 9 is a cross-sectional view of a display device taken along line I-I′ of FIG. 1, according to an embodiment.

In an embodiment, the display device DD described with reference to FIG. 9 may be substantially the same as the display device DD described with reference to FIG. 2 except for including an auxiliary film AL-5 instead of the auxiliary film AL. Additionally, the auxiliary film AL-5 may be substantially the same as the auxiliary film AL except for being disposed between the first electrode E1 and the second electrode E2. Therefore, redundant descriptions are omitted or simplified.

Referring to FIG. 9, in an embodiment, the display device DD may include the auxiliary layer AL-5. The auxiliary layer AL-5 may be disposed on the first electrode E1. That is, the auxiliary layer AL-5 may be disposed between the first electrode E1 and the second electrode E2.

In an embodiment, the auxiliary film AL-5 may include hydrogen (H). Accordingly, hydrogen (H) may flow into the light emitting element LED from the auxiliary film AL-5. That is, hydrogen (H) may flow into the metal oxide layer from the auxiliary film AL-5.

In an embodiment, as the auxiliary film AL-5 is disposed between the first electrode E1 and the second electrode E2, an inflow path of hydrogen (H) flowing from the auxiliary film AL-5 into the metal oxide layer may be shortened as compared to a case where the auxiliary film AL-5 is disposed below the first electrode E1. Accordingly, hydrogen (H) may flow more smoothly from the auxiliary film AL-5 into the metal oxide layer and deterioration of the light emitting element LED may be further reduced or prevented.

In addition, in an embodiment, as the auxiliary film AL-5 is disposed between the first electrode E1 and the second electrode E2, hydrogen (H) supplied from the auxiliary film AL-5 to the metal oxide layer may not be blocked by the first electrode E1. Accordingly, hydrogen (H) may flow more smoothly from the auxiliary film AL to the light emitting element LED and deterioration of the light emitting element LED may be further reduced or prevented.

Specifically, in an embodiment, the auxiliary film AL-5 may be disposed between the first electrode E1 and the intermediate layer ML. In this case, the intermediate layer ML may have the structure described with reference to FIG. 3. That is, the intermediate layer ML may include the hole transport area (HTA, in FIG. 3), the light emitting layer (EML, in FIG. 3), and the electron transport area (ETA, in FIG. 3) sequentially stacked on the first electrode E1. In other words, the light emitting element LED may be a conventional type of light emitting element in which the first electrode E1 is an anode and the second electrode E2 is a cathode.

In an embodiment, as the light emitting element LED is a conventional type of light emitting element and the auxiliary film AL-5 is disposed between the first electrode E1 and the intermediate layer ML, the auxiliary film AL-5 may be disposed between the first electrode E1 and the light emitting layer EML. Specifically, the auxiliary film AL-5 may be disposed between the first electrode E1 and the hole transport area HTA, or between the hole transport area HTA and the light emitting layer EML. For example, the auxiliary film AL-5 may be disposed to directly contact the hole transport area HTA.

In an embodiment, as the auxiliary film AL-5 includes hydrogen (H), the light emitting element LED is a conventional type of light emitting element, and the auxiliary film AL-5 is disposed between the first electrode E1 and the intermediate layer ML, the auxiliary film AL-5 may perform substantially the same role as any one of the layers included in the hole transport area HTA described with reference to FIG. 3. For example, the auxiliary film AL-5 may perform substantially the same role as the hole transport layer described with reference to FIG. 3. In this case, the hole transport area HTA may not include the hole transport layer. However, the invention is not necessarily limited thereto.

In an embodiment, as the auxiliary film AL-5 performs substantially the same role as any one of the layers included in the hole transport area HTA, a structure of the display device DD may be simplified, and efficiency of a manufacturing process of the display device DD may be further improved.

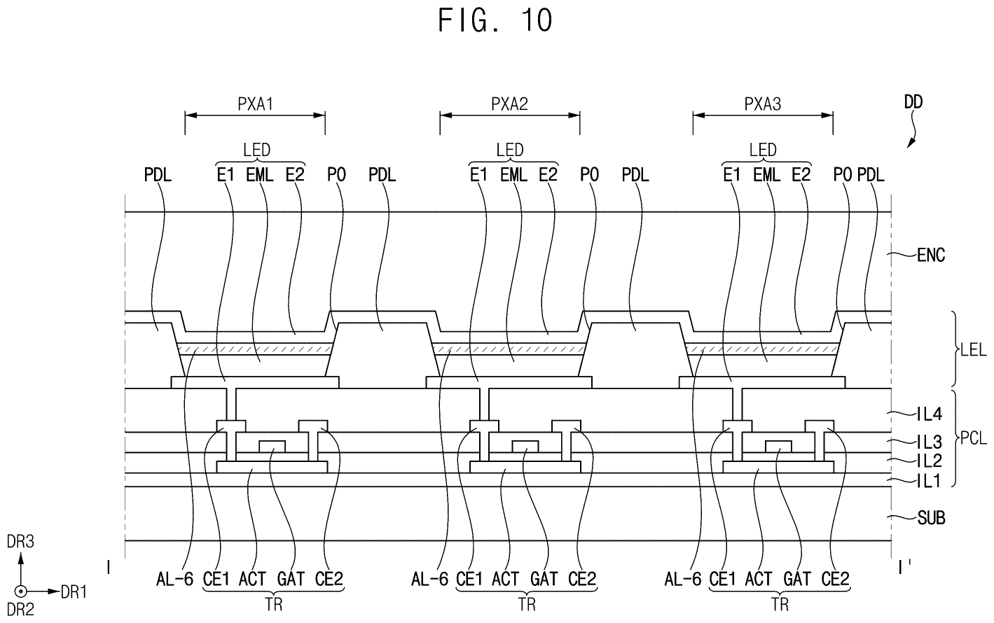

FIG. 10 is a cross-sectional view of a display device taken along line I-I′ of FIG. 1, according to an embodiment.

In an embodiment, the display device DD described with reference to FIG. 10 may be substantially the same as the display device DD described with reference to FIG. 2 except for including an auxiliary film AL-6 instead of the auxiliary film AL. Additionally, the auxiliary film AL-6 may be substantially the same as the auxiliary film AL except for being disposed between the first electrode E1 and the second electrode E2. Therefore, redundant descriptions are omitted or simplified.

Referring to FIG. 10, in an embodiment, the display device DD may include the auxiliary film AL-6, where the auxiliary film AL-6 may be disposed on the first electrode E1. That is, the auxiliary film AL-6 may be disposed between the first electrode E1 and the second electrode E2.

In an embodiment, the auxiliary film AL-6 may include hydrogen (H). Accordingly, hydrogen (H) may flow into the light emitting element LED from the auxiliary film AL-6. That is, hydrogen (H) may flow into the metal oxide layer from the auxiliary film AL-6.

In an embodiment, as explained with reference to FIG. 9, as the auxiliary film AL-6 is disposed between the first electrode E1 and the second electrode E2, hydrogen (H) may flow more smoothly from the auxiliary film AL-6 to the metal oxide layer and deterioration of the light emitting element LED may be further reduced or prevented.

Specifically, in an embodiment, the auxiliary film AL-6 may be disposed between the intermediate layer ML and the second electrode E2. In this case, the intermediate layer ML may have the structure described with reference to FIG. 4. That is, the intermediate layer ML may include the electron transport area (ETA, in FIG. 4), the light emitting layer (EML, in FIG. 4), and the hole transport area (HTA, in FIG. 4) sequentially stacked on the first electrode E1. In other words, the light emitting element LED may be an inverted type of light emitting element in which the first electrode E1 is a cathode and the second electrode E2 is an anode.

In an embodiment, as the light emitting element LED is an inverted type of light emitting element and the auxiliary film AL-6 is disposed between the intermediate layer ML and the second electrode E2, the auxiliary film AL-6 may be disposed between the light emitting layer EML and the second electrode E2. Specifically, the auxiliary film AL-6 may be disposed between the light emitting layer EML and the hole transport area HTA, or between the hole transport area HTA and second electrode E2. For example, the auxiliary film AL-6 may be disposed to directly contact the hole transport area HTA.

In an embodiment, as the auxiliary film AL-6 includes hydrogen (H), the light emitting element LED is an inverted type of light emitting element, and the auxiliary film AL-6 is disposed between the intermediate layer ML and the second electrode E2, the auxiliary film AL-6 may perform substantially the same role as any one of the layers included in the hole transport area HTA described with reference to FIG. 4. For example, the auxiliary film AL-6 may perform substantially the same role as the hole transport layer described with reference to FIG. 4. In this case, the hole transport area HTA may not include the hole transport layer. However, the invention is not necessarily limited thereto.

In an embodiment, as the auxiliary film AL-6 performs substantially the same role as any one of the layers included in the hole transport area HTA, a structure of the display device DD may be simplified, and efficiency of a manufacturing process of the display device DD may be further improved.

According to embodiments, the display device DD may include an auxiliary film including hydrogen (H), where hydrogen (H) may flow into the light emitting element LED from the auxiliary film.

In an embodiment, as hydrogen (H) flows into the metal oxide layer from the auxiliary film, the oxygen vacancy of the metal oxide layer may be reduced and deterioration of the metal oxide layer due to oxygen vacancy may be reduced or prevented. Accordingly, deterioration of the light emitting element LED may be reduced or prevented and luminous efficiency of the display device DD may be improved.

In particular, according to an embodiment, the auxiliary film may be disposed on at least one of the same level as the first electrode E1, and a level between the first electrode E1 and the second electrode E2. Accordingly, a distance between the auxiliary film and the metal oxide layer may be reduced as compared to a case where the auxiliary film is disposed below the first electrode E1. Accordingly, an inflow path of hydrogen (H) flowing from the auxiliary film AL into the metal oxide layer may be shortened. Accordingly, hydrogen (H) may flow more smoothly from the auxiliary film AL into the metal oxide layer and deterioration of the light emitting element LED may be further reduced or prevented.

In addition, in an embodiment, as the auxiliary film is disposed on at least one of the same level as the first electrode E1, and a level between the first electrode E1 and the second electrode E2, hydrogen (H) supplied from the auxiliary film AL to the metal oxide layer may not be blocked by the first electrode E1. Accordingly, hydrogen (H) may flow more smoothly from the auxiliary film AL to the light emitting element LED and deterioration of the light emitting element LED may be further reduced or prevented.

The invention should not be construed as being limited to the embodiments set forth herein. Rather, these embodiments are provided so that this disclosure will be thorough and complete and will fully convey the concept of the invention to those skilled in the art. Although a few embodiments have been described, those skilled in the art will readily appreciate that many modifications are possible in the embodiments without materially departing from the novel teachings and advantages of the invention. Accordingly, all such modifications are intended to be included within the scope of the invention as disclosed in the specification and figures and/or as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the invention. Moreover, the embodiments or parts of the embodiments may be combined in whole or in part without departing from the scope of the invention.

1. A display device comprising:
a first electrode;
a second electrode disposed on the first electrode and facing the first electrode;
a light emitting layer disposed between the first electrode and the second electrode and including a quantum dot;
a metal oxide layer disposed between the first electrode and the second electrode and including a metal oxide;
an auxiliary film disposed at the same level as the first electrode and including an inorganic material; and
a pixel defining layer which covers at least a portion of the auxiliary film and which defines a pixel opening exposing a portion of the first electrode.

2. The display device of claim 1, wherein the auxiliary film includes hydrogen.

3. The display device of claim 2, wherein the auxiliary film has a hydrogen content sufficient to emit hydrogen gas of about 1.0E+20 molecules/cm³ or more when the auxiliary film is heated to a temperature range of about 50° C. to about 550° C.

4. The display device of claim 1, wherein the inorganic material includes at least one of silicon oxide, silicon nitride, and silicon oxynitride.

5. The display device of claim 4, wherein the auxiliary film is continuously connected between a plurality of pixel areas which are disposed adjacent to each other and which are defined by the pixel opening.

6. The display device of claim 1, wherein the inorganic material includes silicon semiconductor.

7. The display device of claim 6, wherein the auxiliary film is disconnected between a plurality of pixel areas which are disposed adjacent to each other and which are defined by the pixel opening.

8. The display device of claim 1, wherein the auxiliary film covers a portion of the first electrode and exposes another portion of the first electrode.

9. The display device of claim 1, wherein the auxiliary film is disposed to be spaced apart from the first electrode.

10. The display device of claim 1, wherein the metal oxide includes zinc-containing oxide.

11. The display device of claim 10, wherein the metal oxide layer includes Mg-doped ZnO (ZnMgO).

12. The display device of claim 1, wherein the pixel defining layer has liquid repellency.

13. The display device of claim 1, further comprising an electron transport area disposed between the first electrode and the second electrode,
wherein the metal oxide layer is included in the electron transport area, and
wherein the electron transport area is disposed to be between at least one of the first electrode and the light emitting layer, and the second electrode and the light emitting layer.

14. The display device of claim 13, wherein the electron transport area includes at least one layer of a buffer layer, a hole blocking layer, an electron control layer, an electron transport layer, and an electron injection layer, and
wherein the metal oxide layer is at least one of the buffer layer, the hole blocking layer, the electron control layer, the electron transport layer, and the electron injection layer.

15. A display device comprising:
a first electrode;
a second electrode disposed on the first electrode and facing the first electrode;
a light emitting layer disposed between the first electrode and the second electrode and including a quantum dot;
a metal oxide layer disposed between the first electrode and the second electrode and including a metal oxide;
an auxiliary film disposed between the first electrode and the second electrode and including an inorganic material; and
a pixel defining layer which covers at least a portion of the auxiliary film and which defines a pixel opening exposing a portion of the first electrode.

16. The display device of claim 15, wherein the auxiliary film includes hydrogen.

17. The display device of claim 16, wherein the auxiliary film has a hydrogen content sufficient to emit hydrogen gas of about 1.0E+20 molecules/cm3 or more when the auxiliary film is heated to a temperature range of about 50° C. to about 550° C.

18. The display device of claim 15, wherein the inorganic material includes at least one of silicon oxide, silicon nitride, silicon oxynitride, and silicon semiconductor.

19. The display device of claim 15, wherein the metal oxide includes zinc-containing oxide.

20. The display device of claim 19, wherein the metal oxide layer includes Mg-doped ZnO (ZnMgO).

21. The display device of claim 15, further comprising a hole transport area disposed between the first electrode and the second electrode, and
wherein the auxiliary film is disposed to be between at least one of the first electrode and the light emitting layer, and the second electrode and the light emitting layer.

22. The display device of claim 15, further comprising an electron transport area disposed between the first electrode and the second electrode,
wherein the metal oxide layer is included in the electron transport area, and
wherein the electron transport area is disposed to be between at least one of the first electrode and the light emitting layer, and the second electrode and the light emitting layer.

23. The display device of claim 22, wherein the electron transport area includes at least one layer of a buffer layer, a hole blocking layer, an electron control layer, an electron transport layer, and an electron injection layer, and
wherein the metal oxide layer is at least one of the buffer layer, the hole blocking layer, the electron control layer, the electron transport layer, and the electron injection layer.

24. A display device comprising:
a substrate;
a pixel circuit layer disposed on the substrate and including at least one transistor and a planarization layer covering the transistor; and
a light emitting element layer disposed on the pixel circuit layer,
wherein the light emitting element layer includes,
a first electrode disposed on the planarization layer;
a second electrode disposed on the first electrode and facing the first electrode;
a light emitting layer disposed between the first electrode and the second electrode and including a quantum dot;
a metal oxide layer disposed between the first electrode and the second electrode and including a metal oxide;
an auxiliary film disposed on at least one of the same level as the first electrode, and a level between the first electrode and the second electrode and including an inorganic material; and
a pixel defining layer which covers at least a portion of the auxiliary film and which defines a pixel opening exposing a portion of the first electrode.

25. The display device of claim 24, wherein the auxiliary film includes hydrogen, and
the metal oxide included in the metal oxide layer includes zinc-containing oxide.

26. The display device of claim 24, wherein the inorganic material includes at least one of silicon oxide, silicon nitride, silicon oxynitride, and silicon semiconductor.
